(19) United States
(12) Patent Application Publication
(10) Pub. No.: US 2024/0107698 A1
(43) Pub. Date: Mar. 28, 2024

(54) SCALABLE, ADAPTABLE AND MODULAR INTEGRATED UNITS FOR ASSEMBLING A PLURALITY OF INFRASTRUCTURAL SYSTEMS

(71) Applicant: QOGNO DIGITAL INFRASTRUCTURE PVT LTD, Bangalore, Karnataka (IN)

(72) Inventors: Gururaj NAYAK, Bangalore, Karnataka (IN); Abhishek -, Bangalore, Karnataka (IN); Ambarish SAUNGIKAR, Bangalore, Karnataka (IN)

(21) Appl. No.: 17/766,264

(22) PCT Filed: Aug. 25, 2020
(86) PCT No.: PCT/IB2020/057924

§ 371 Date: Apr. 4, 2022

(30) Foreign Application Priority Data
Oct. 3, 2019 (IN) 201941040002

(51) Int. Cl. H05K 7/02

(52) U.S. Cl. CPC H05K 7/023; H05K 7/026

(57) ABSTRACT

The present invention provides a system (100) built using scalable, adaptable and modular integrated units for assembling a plurality of infrastructural systems. The system (100) comprises of at least one base unit (101) that may comprise an upper sub-unit, a middle sub-unit and a lower sub-unit that together contain a plurality of devices or instruments that enable external and internal communications. One or more block units (102) are disposed atop the base unit (101) and connect to the base unit (101) by means of multi-directional linking mechanisms which provide structural integrity and enable communication between the block unit (102) and base unit (101). Further, one or more mount units (103) enable the fitment of various external peripheral devices that are chosen based on user's requirement.

### DESCRIPTION OF THE INVENTION

### Technical field of the Invention

The present invention provides scalable, adaptable and modular integrated units which are employed for assembling a plurality of infrastructural systems. The present invention particularly relates to scalable, adaptable and modular, integrated units which are connected and controlled through single or multi-channel transmission and for communication connectors integrated with a plurality of control mechanisms.

### Background of the Invention

The present generation signal communication structures such as communication systems have limited utility and are limited to purely communication capabilities. Presently, there are no provisions for modifying the structure to preferred applications as per the user's requirements and in the event of repairs or replacement of the equipment and/'or device, a large amount of time, money & effort is expended due to the complex nature of the communication devices and the manner in which they are attached to the system. Furthermore, tasks such as approval on various types of permissions, place or site allocation, certifications, execution timelines and so on, lead to time consuming, expensive, non-standardized and non-coordinated approaches which further result in redundancy, inconsistency and loss of network effect due to poor planning and execution.

For instance, in the event that a new application or function is required to be installed or integrated in the system, there is always a need to introduce a new 25 device which becomes a painstaking task as the connections between the main body of the system and the device may not be compatible with each other. Since the parts are obtained from different vendors, it is impossible to guarantee a uniform level of quality of the devices. Further, different vendors provide different pricings for the same device, which leads to higher purchase costs and further non-uniformity. Additionally, in the process of assembling and integrating new devices or equipment, the consequences of such installation on the network connectivity i.e. the network effect of the system has not been considered.

Technology today has not yet reached the envisioned goal where devices and systems may communicate with each other to optimise network communication systems. The visage of separate Vendors and device software results in devices having the capacity to work more efficiently by means of networking but not being able to do so because of lack of communication between the vendors and lack of knowledge to the full capabilities of the network.

The patent application Ser. No. US3768016A discloses an integrated, modular, prefabricated communications relay system, comprising a plurality of tubular modules prefabricated in a shop facility with the necessary accessory devices therein and assembled in end-to-end relationship at the site of the relay system to provide a complete integrated, modular relay system with the necessary accessory devices and electronic equipment therein.

Hence, there exists a need for a system which enables customization of structures which act as hosts for ease of scalability to new technologies, ease of adaptability to new services and ease of modularity to accommodate new devices, with the flexibility to be utilized for various applications as per users' requirements and ensures uniformity in the system for improved network communication.

### SUMMARY OF THE INVENTION:

The present invention overcomes the drawbacks of the current technology by providing scalable, adaptable and modular integrated units for assembling a plurality of infrastructural systems. The resultant system comprises at least one base unit which may be divided into a plurality of sub-units such as upper sub-unit. middle sub-unit and lower sub-unit, wherein the upper sub-unit comprises an indicator lighting system and a base unit to block unit linking mechanism. The middle sub-unit comprises a plurality of devices and equipments which are employed for interactive and/or non-interactive applications and the lower sub-unit comprises a plurality of devices and/or equipments for facilitating the provision for computation, communication and/or power supply thereby forming the back-bone connectivity grid of the system. The base unit comprises a plurality of devices and/or equipments for enabling internal and external communication and computation.

Further, the system also comprises one or more block units which are placed atop the base unit, wherein the block unit is connected to the base unit through a single or multi-directional linking mechanism which provides structural integrity to the system. The linking mechanism employs one or more connectors that enable communication between the block unit and base unit, wherein the connectors allow the transmission of power signals, data signals and so on. Furthermore, the system comprises one or more mount units for enabling the fitment of a plurality of external peripheral devices depending on the user's requirement and are locally and/or remotely monitored and/or controlled using a single or multi-channel transmission and/or communication connector. The base, block and mount units are scalable, adaptable and modular as per the future technological requirements and allow the integration of futuristic devices and equipments.

The present invention overcomes several drawbacks which are encountered in the present-day communication systems. Due to the adaptable behavior of the present invention, it is a simple task to upgrade or downgrade the system to better suit the user's requirements. Block units may be stacked on top of one another in any desirable spatial orientation and third-party devices may be added or removed as per requirement, thereby making the system modular. Communication connectors and linkages make it feasible to attach a plurality of block units, thereby expanding the computing power and accessibility of the system for better functionality. Additionally, due to the nature of the communication connectors and linkages, future technologies may also be easily accommodated into system, thereby making it scalable.

### BRIEF DESCRIPTION OF THE DRAWINGS:

The foregoing and other features of embodiments will become more apparent from the following detailed description of embodiments when read in conjunction with the accompanying drawings, In the drawings, like reference numerals refer to like elements,

FIG. 1 illustrates a system built using scalable, adaptable and modular integrated units for assembling a plurality of infrastructural systems.

FIG. 2 illustrates a base unit which comprises a plurality of devices and/or equipments for enabling internal and/or external communication and computation.

FIG. 3 illustrates a block unit which is connected to the base unit through a single or multi-directional linking mechanism.

FIG. 4 illustrates a mount unit for enabling the fitment of a plurality of external peripheral devices depending on user's requirement.

### DETAILED DESCRIPTION OF THE INVENTION:

Reference will now he made in detail to the description of the present subject matter, one or more examples of which are shown in figures. Each example is provided to explain the subject matter and not a limitation. Various changes and modifications obvious to one skilled in the art to which the invention pertains are deemed to be within the spirit, scope and contemplation of the invention.

The present invention provides a system (100) built using scalable, adaptable and modular integrated units for assembling a plurality of infrastructural systems. The system (100) comprises of at least one base unit (101) which may be divided into a plurality of sub-units such as an upper subunit, a middle sub-unit and a lower sub-unit which comprise a plurality of devices and/or equipments that enable external and internal communication. One or more block units (102) are disposed atop the base unit (101) and connect to the base unit (101) by means of single or multi-directional linking mechanisms which provide structural integrity and enable communication between the block unit (102) and base unit (101). The communication is facilitated by one or more connectors that allow the transmission of power signals, data signals and so on. Further, one or more mount units (103) enable the fitment of various external peripheral devices that are chosen based on user's requirement.

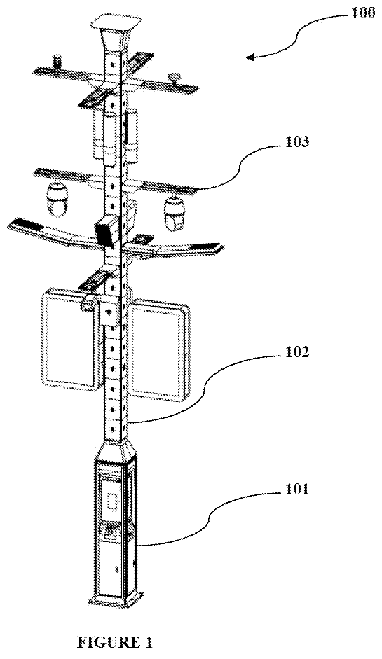

FIG. 1 illustrates a system (100) built using scalable, adaptable and modular integrated units for assembling a plurality of infrastructural systems, wherein the system (100) comprises at least one base unit (101) which houses a plurality of devices and/or equipments for enabling internal and external communication and computation. In one embodiment, the base unit (101) may be a kiosk which comprises a plurality of interactive and for non-interactive applications and multiple levels of functionality. The base unit (101) may contain a plurality of devices with interactive functionalities such as Save our Soul (SoS) alert systems, surveillance cameras, biometric authenticators, indicator lights, Universal Serial Bus (USB) charging ports, power systems, Internet of Things (IoT) devices and so on. The base unit (101) connects to the foundation, integrating the last mile connectivity to the base unit (101), and so on, thereby providing seamless and frictionless communication between an Integrated Command and Control Center (ICCC) and the base unit (101).

The base unit (101) comprises devices and/or equipments for enabling internal and external communication within the base unit (101). Further, the base unit (101) may be divided into a plurality of sub-units such as the upper sub-unit, middle sub-unit and lower sub-unit, wherein the upper sub-unit may house programable indicator lights and a provision to establish connection between the base unit (101) and a block unit (102) by means of mechanical connectors and linkages. The upper sub-unit also provides a linkage mechanism for connecting the base unit (101) to at least one block unit (102) that may be stacked over the base unit (101), wherein communication between the base unit (101) and block unit (102) is facilitated by mechanical connectors integrated with a plurality of control. mechanisms such as intelligent microchips.

The middle sub-unit of the base unit (101) comprises a plurality of interactive devices such as computer displays, screens, cameras. biometric authenticators, USB charging ports. SoS panic alert systems and so on. The middle sub-unit is connected to the base unit (101) through smart communication lines that are responsible for transmitting loss-less information efficiently. The lower sub-unit of the base unit (101) houses all the computational devices such as switchable hatches for enabling tasks associated with maintenance and upgradation of the system (100), Uninterruptible Power Sources (USPs), Switched Mode Power Supplies (SMPSs), electronic and electrical IoT based devices, channels for communication and power lines. The lower sub-unit is also responsible for delivering power to the base unit (101) and consequently the entire system (100). All the devices and/or equipments of the base unit (101) are designed to be scalable, adaptable and modular such that replacing, repairing and changing of the devices and for equipments is a hassle-free process and requires minimum time and effort

One or more block units (102) are disposed atop the base unit (101), wherein the block unit (102) is connected to the base unit (101) through a single or multi-directional linking mechanism which provides structural integrity to the system (100) and enables communication between the block unit (102) and base unit (101) using one or more connectors which allow the transmission of power . signals, data signals and so on. The block unit (102) comprises single or multi-channel transmission and/or communication connectors, structural elements such as mechanical linkages and an exterior frame for providing shape and structure, microchips, linking points and so on. The single or multi-channel transmission and/or communication connectors are customized signal communication devices which communicate between the block units (102), within the block unit (102), between block unit (102) and base unit (101), between the block units (102) and foundation and between the block units (102) and mounted accessories.

The connectors transfer both power and/or data signals for multiple requirements to the respective devices, wherein the power and/or data transfer are controlled and channelized through a plurality of control mechanisms such as a microchip which is disposed within the block unit (102). The microchip is an integrated module which is scalable, adaptable and modular and provides the flexibility of upgrading to the existing or futuristic technology. It may comprise relays, switches, micro-controllers or System on Chips (SoCs), data and power sockets, electrical and electronic communicating devices, sensors and so on. Further, the block units (102) form a multi-directional communication unit which withstands the structural loads of the system (100) by virtue of the single or multi-channel transmission and/or communication connectors, wherein the single or multi-channel transmission and or communication connectors integrated with the microchip provide access to the backbone connectivity grid of the system (100).

The system (100) comprises one or more mount units (103) for enabling the fitment of a plurality of external peripheral devices depending on user's requirement. The mount unit (103) is an accessory bearing component which may comprise linking points, devices that house provisions for structural elements, single or multi-channel transmission and/or communication connectors for power and/or data communication, power and/or data, converters and so on. The mount unit (103) comprises provisions to withstand extreme environmental conditions and mechanical loads exerted by a plurality of devices and/or equipments such as surveillance systems, street lighting systems, digital or static signages, hoardings, Wi-fi modules, and so on.

The mount unit (103) is designed as per the user's requirement to enable communication with the backbone connectivity grid, wherein the attached devices and/or equipments may be controlled remotely or locally using the single or multi-channel transmission and/or communication connectors of the mount unit (103) which is integrated with microchip of the block unit (102). The communication signals may be connected or routed through the backbone connectivity grid of the system (100) and subsequently, to the remote ICCC or any desired location. The accessories winch are mounted on the system (100) through the mount units (103) may be third-party devices ands or equipments, such as Closed Circuit Television (CCTV) cameras, digital or static signages, access points, street lighting assemblies, solar panels, wireless communication sites, environmental sensors, drone charging stations, outlets and communication pads, small cells, signal communication devices and/or equipment, beckons, hoardings, and so on. Mount units (103) are designed to house various linking points that are used to attach the third-party devices and/or equipments to the system (100). Further, the integrated units are also capable of withstanding extreme weather conditions and are less susceptible to environmental damage.

According to one or more embodiments of the present invention, the system (100) may be a signal communication tower which comprises the base unit (101), one or more block units (102) and one or more mount units (103) for facilitating the attachment of a plurality of external third-party devices. In this embodiment, the base unit (101) is attached to the foundation and is structurally strong to ensure stability of the system (100). The foot of the base unit (101) enables the connectivity through wired or wireless provisions which ensures the connectivity of the entire system (100). The base unit (101) may function independently as a kiosk, information center, vending machine and so on and may also house one or more block units (102). As per the user's requirements, the block units (102) may be mounted on the base unit (101) in any spatial orientation i.e. horizontally, vertically or at any desired angle. Together with the block units (102), the system (100) may function as an interactive kiosk with multiple added functionalities that are introduced by the addition of third-party devices and/or equipments such as digital signages, loudspeakers, surveillance systems, WiFi modules, intercoms, Electric Vehicle (EV) chargers, indicator lights, solar panels, drone charging units and communication pads, IOT devices and so on.

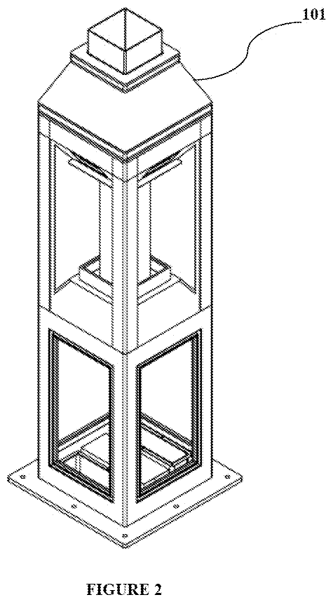

FIG. 2 illustrates a base unit (101) which may comprise the upper sub-unit, middle sub-unit and lower sub-unit, wherein the upper sub-unit provides a linkage mechanism for connecting the base unit (101) to at least one block unit (102) that may be stacked over the base unit (101), wherein communication between the base unit (101) and block unit (102) is facilitated by mechanical connectors integrated with intelligent microchips. The middle sub-unit of the base unit (101) may comprise all the interactive devices such as computer displays, screens, cameras, biometric authenticators, USB charging ports, SoS panic alert systems and so on.

The lower sub-unit of the base unit (101) houses all the computational devices such as switchable hatches for enabling tasks associated with maintenance and upgradation of the system (100), Uninterruptible Power Sources (USPs), Switched Mode Power Supplies (SMPSs), electronic and electrical IOT based devices, channels for communication and power lines. The lower sub-unit is responsible for delivering power anchor data to the base unit (101) and consequently the entire system (100),

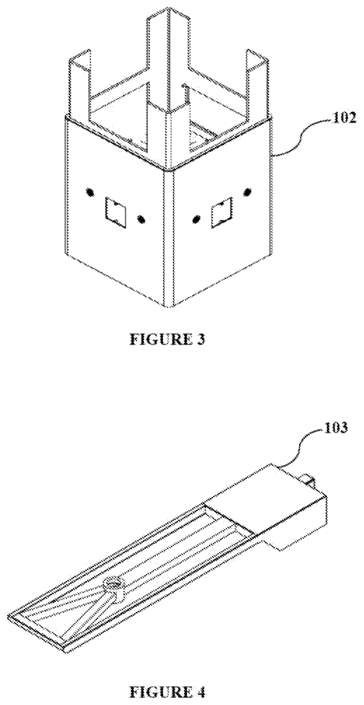

FIG. 3 illustrates a block unit (102) winch is connected to the lase Unit (101) through a multi-directional linking mechanism which provides structural integrity to the system (100) and enables communication between the block unit (102) and base unit (101) using one or more connectors which allow the transmission of power and/or data signals and so on. The block unit (102) comprises single or multi-channel transmission and/or communication connectors, structural elements such as mechanical linkages and an exterior frame for providing shape and structure, microchips, linking points and so on. The single or multi-channel transmission and/or communication connectors are customized signal communication devices which communicate between the block units (102), within the block unit (102), between block units (102) and base units (101), between the block units (102) and foundation and between the block unit (102) and mounted accessories.

FIG. 4 illustrates a mount unit (103) for enabling the fitment of a plurality of external peripheral devices depending on user's requirement. The mount unit (103) is an accessory bearing device Which comprises linking points, devices that house provisions for structural elements, single or multi-channel transmission and/or communication connectors for power and/or data communication, power and/or data converters and so on. The mount unit (103) may withstand extreme environmental conditions and mechanical loads exerted by a plurality of devices and/or equipments such as surveillance systems, street lighting systems, digital or static signages, hoardings, modules, and so on.

In one embodiment, the system (100) may comprise a base unit (101) which is independently mounted on the foundation thereby acting as a kiosk which may have utility in movie theatres, transportation terminals and so on. hi another embodiment, the system (100) may comprise a plurality of block units (102) which may be mounted on the foundation in any spatial orientation i.e. horizontally, vertically or at any desired angle. The block units (102) enable the transfer and communication of data signals, power signals and so on through a plurality of control mechanisms such as microchips which are embedded in each block unit (102). Further, one or more mount units (103) many be connected to the block units (102) for enabling the fitment of a plurality of external peripheral devices depending on user's requirement,

The integrated units i.e. the base unit (101), the block unit (102) and the mount unit (103) have been designed in accordance to the principles of scalability, adaptability and modularity, wherein the term “scalable” implies that the units have provisions to be upgraded to a plurality of futuristic technologies. The term “adaptable” implies that the integrated units are designed such that the they allow the integration of a plurality of devices and/or equipments to obtain multiple embodiments of the present invention.

The ability to house appliances both in the present and future applications of the embodiment makes the system (100) adaptable with reference to technological advances. The term “modular” implies that the integrated units are designed such that replacing, repairing and changing of the devices and/or equipments is a hassle-free process. Further, the integrated units are interchangeable and replaceable due to their modular design and have the capacity to be removed or added without any significant wastage of time and/or effort. Further, the present invention also enables the system (100) to communicate with a plurality of similar infrastructural systems and IoT enabled devices and/or equipments to achieve an improve network effect.

While at least one exemplary embodiment has been presented in the foregoing detailed description, it should be appreciated that a vast number of variations exist.

Reference numbers:

| Components | Reference Numbers |
|---|---|
| System | 100 |
| Base unit | 101 |
| Block unit | 102 |
| Mount unit | 103 |

We claim:

1. A system (100) built using sealable, adaptable and modular integrated units for assembling a plurality of infrastructural systems, the system (100) comprising:
a. at least one base unit (101) which comprises a plurality of devices and/or equipments for enabling internal and/or external. communication and computation;
b. one or more block units (102) which are disposed atop the base unit (101), wherein the block unit (102) is connected to the base unit (101) through a single or multi-directional linking mechanism which provides structural integrity and enables communication between the block unit (102) and base unit (101) using one or more connectors which allow the transmission of power and/or data. signals;
c. one or more mount units (103) for enabling the fitment of a plurality of external peripheral devices depending on user's requirement.

2. The system (100) as claimed in claim 1, wherein the block units (102) are disposed one over the other and are scaled up or down to a pre-defined height as per the user's requirement.

3. The system (100) as claimed in claim 1, wherein one or more block units (102) are connected using connectors integrated with control mechanisms for facilitating single or multi-channel transmission and/or communication between one or more block units (102), within one block unit (102), between the base unit (101) and block unit (102) and/or block unit (102) and mount units (103).

4. The system (100) as claimed in claim 1, wherein a plurality of block units (102) is assembled vertically, horizontally and/or at a pre-defined angle as per the user's requirement.

5. The system (100) as claimed in claim 1, wherein the control mechanisms which control and channelize the transfer of power and/or data signals are scalable, adaptable and modular thereby provides flexibility of upgrading to the existing and/or futuristic requirements.

6. The system (100) as Claimed in claim 1, wherein the mount units (103) facilitate the fitment of external peripheral devices which are locally and/or remotely monitored and/or controlled using single or multi-channel transmission and/or communication connectors integrated with control mechanisms provided in each block unit (102) of the system (100).

7. The system (100) as claimed in claim 1, wherein the base unit (101), block units (102) and mount units (103) are scalable and adaptable to future technologies and allow the integration of futuristic devices and/or equipments.
